(19) United States
(12) Patent Application Publication
(10) Pub. No.: US 2009/0224844 A1
(43) Pub. Date: Sep. 10, 2009

(54) EXTENDED RANGE OSCILLATOR

(75) Inventors: Omer Fatih Orberk, Istanbul (TR); Alexei Shkidt, Newark, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SpectraLinear, Inc., Santa Clara, CA (US)

(21) Appl. No.: 12/395,854

(22) Filed: Mar. 2, 2009

Related U.S. Application Data
(60) Provisional application No. 61/033,517, filed on Mar. 4, 2008.

(51) Int. Cl. H03L 5/00

(52) U.S. Cl. 331/183

(57) ABSTRACT

Embodiments provide systems and methods for supporting reliable operation of crystals with widely varying fundamental modes of oscillation. In accordance with exemplary embodiments, an architecture is disclosed for an oscillator circuit which allows reliable operation for crystals varying over a wide frequency range, such as 12:1. Some embodiments use selectable current sources to provide variable range control for extending the range of frequencies over which the embodiments may operate properly. Other embodiments include symmetric topologies, cascode topologies, coupling elements, and/or other techniques to improve noise immunity and/or operation in low-source-voltage environments.

### CROSS-REFERENCE

This application claims priority from co-pending U.S. Provisional Patent Application No. 61/033,517, filed Mar. 4, 2008, entitled “EXTENDED RANGE OSCILLATOR” (Attorney Docket No. 026292-000700US), which is hereby incorporated by reference, as if set forth in full in this document, for all purposes.

### BACKGROUND

The present invention relates generally to integrated circuits, and more particularly to oscillator support circuits.

The ability to change operating frequency within a system is valuable to accommodate technologies with continually improving performance and data rates. Therefore, it is valuable to design products and systems capable of operating over an ever broadening range of frequencies. To support these applications, crystals are cut to certain sizes and with cut faces of particular orientation to the inherent lattice structure to provide desired frequencies of oscillation. However, in the area of crystal oscillator circuit design, there may be a tradeoff between ensuring fundamental oscillation at high frequencies without inducing harmonic oscillations at lower frequencies.

For example, an oscillator cut for high-frequency operation may require high gain for optimal functionality. Further, during startup of an oscillator, the magnitude of gain applied to the crystal may be even higher, depending on desired oscillation frequency, capacitance values of loading capacitors, electrical characteristics of the crystal, etc. If a circuit is to be used with crystals cut for both low-frequency and high-frequency fundamental oscillation, the gain of the circuit may typically be sub-optimal for some cases. On one hand, applying a gain that is too low may prevent startup of higher-frequency crystal oscillators. On another hand, applying a gain that is too high may cause lower-frequency oscillators to oscillate in harmonic modes, rather than at their fundamental frequency. As such, balancing these issues may limit the range of oscillator frequencies supported by many circuits.

It may be desirable to have a crystal oscillator circuit capable of operating over an extended range of frequencies and able to initiate oscillation under various expected startup conditions with an appropriate gain applied to the crystal. Additionally, it would be desirable to have a crystal oscillator circuit with configurable gain capabilities to tailor an amount of gain provided by the circuit according to the crystal used and frequency of operation desired.

### BRIEF SUMMARY

Among other things and in accordance with exemplary embodiments, an architecture is disclosed for an oscillator circuit which allows reliable operation for crystals varying over a wide frequency range, such as 12:1. Some embodiments use selectable current sources to provide variable range control for extending the range of frequencies over which the embodiments may operate properly. Other embodiments include symmetric topologies, cascode topologies, coupling elements, and/or other techniques to improve noise immunity and/or operation in low-source-voltage environments.

In one set of embodiments, oscillator circuits are provided. The oscillator circuits include: a gain module, configured to output an oscillator output signal as a function of applying a gain current to an oscillation device; a comparison module, in operative communication with the gain block and configured to: receive an input signal having an input signal level that is functionally related to an amplitude of the oscillator output signal; monitor a difference between the input signal level and a reference level; and produce a feedback level as a function of the difference between the input signal level and the reference level; and a current source module, comprising a foundation current block and a selectable current block, each of the foundation current block and the selectable current block being in operative communication with the comparison block and the gain block, and each of the foundation current block and the selectable current block being configured to independently generate at least a portion of the gain current as a function of the feedback level and to provide the gain current to the gain block, the selectable current block comprising a select device configured to enable the selectable current block as a function of a selection input.

In another set of embodiments, other oscillator circuits are provided. The oscillator circuits include: a gain stage coupled to a supply voltage reference node and configured to provide a magnitude of gain corresponding to a feedback signal, the gain stage comprising a plurality of gain sources, each of the gain sources being in communication with the feedback signal, and at least one of the gain sources being configured to be disabled; and a gain control stage, coupled to the gain stage and configured to measure a magnitude of difference between a direct-bias input signal level and a reference signal level and produce the feedback signal proportional to the difference measured.

In yet another set of embodiments, a method for regulating an amplitude of an oscillation output signal is provided. The method includes: receiving an input signal having an input signal level that is functionally related to the amplitude of the oscillator output signal, the oscillator output signal being generated as a function of applying a gain current to an oscillation device, the oscillation device being configured to oscillate substantially at a fundamental frequency; monitoring a difference between the input signal level and a reference level; producing a feedback level as a function of the difference between the input signal level and the reference level; and controlling the gain current as a function of the feedback level, wherein the gain is controlled within a gain range selected according to the fundamental frequency of the oscillation device.

### BRIEF DESCRIPTION OF THE DRAWINGS

A further understanding of the nature and advantages of the present invention may be realized by reference to the following drawings. In the appended figures, similar components or features may have the same reference label. Further, various components of the same type may be distinguished by following the reference label by a second label that distinguishes among the similar components (e.g., a lower-case character). If only the first reference label is used in the specification, the description is applicable to any one of the similar components having the same first reference label irrespective of the second reference label.

FIG. 1 shows a high level schematic diagram of an embodiment of an oscillator circuit, according to various embodiments of the invention.

FIG. 2 shows a functional block diagram illustrating a crystal oscillator circuit that supports a wide range of frequencies, according to various embodiments of the invention.

FIG. 3A shows a schematic diagram for providing illustrative gain stage functionality, according to various embodiments of the invention.

FIG. 3B shows a schematic diagram for providing illustrative feedback control stage functionality, according to various embodiments of the invention.

FIG. 4 illustrates another simplified block diagram of a circuit arrangement, for use with various embodiments of the invention.

FIG. 5 shows a flow diagram of a method for regulating an amplitude of an oscillator output signal, according to various embodiments of the invention

### DETAILED DESCRIPTION

Among other things, embodiments provide systems and methods for supporting reliable operation of crystals with widely varying fundamental modes of oscillation.

Crystal oscillators may be built around a crystal that has been configured (e.g., cut) to oscillate at a particular fundamental frequency when excited. Often, oscillators cut for higher-frequency operation may require higher currents (e.g., higher gains) for optimal functionality. Further, during startup, the magnitude of gain applied to the crystals may be even higher, depending on desired oscillation frequency, capacitance values of loading capacitors, electrical characteristics of the crystal, etc. As the crystal oscillates, it may be desirable to control the amplitude and other characteristics of the oscillation to generate a desired oscillator output signal.

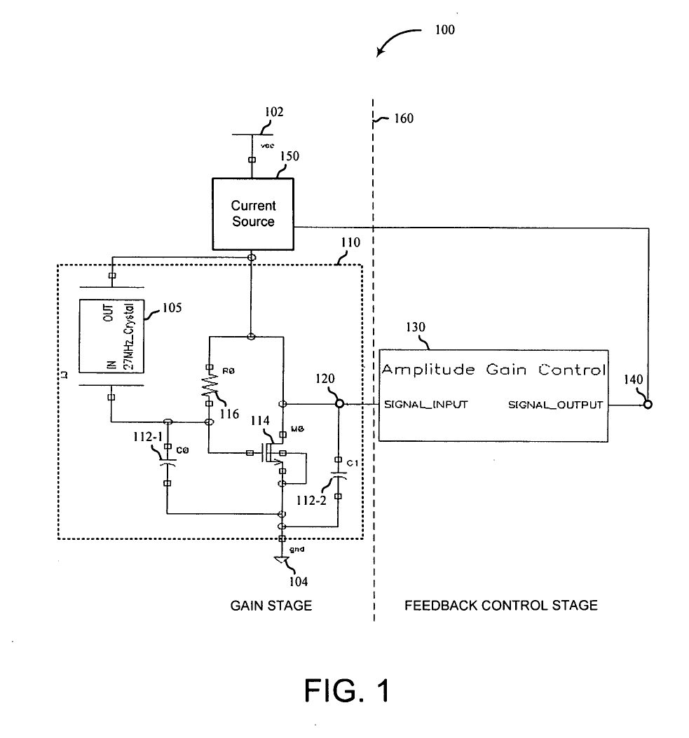

FIG. 1 shows a high level schematic diagram of an embodiment of an oscillator circuit 100, according to various embodiments of the invention. The oscillator circuit 100 includes an oscillation block 110 for generating an oscillation output signal. The oscillation block 110 is driven by a current source 150 (both shown on the left side of divider 160 as a gain stage), which is regulated in feedback by an amplitude gain control (“AGC”) block 130 (shown on the right side of divider 160 as a feedback control stage). The current source 150 generates a desired current output at least partially from its connection to a source voltage 102.

The AGC block 130 receives an input signal at its signal input node 120, which relates to the amplitude of the oscillator output signal. The AGC block 130 compares the input signal to an internal reference voltage, and generates an output signal at its signal output node 140 as a function of the comparison. The output signal is used as a feedback signal (e.g., as a negative feedback loop) to regulate the current output of the current source 150. Regulating the current output may effectively regulate the amplitude of the oscillator output signal. For example, as the amplitude of the oscillator output signal increases, the AGC block 130 may feedback a signal to reduce the current output of the current source 150, thereby causing the amplitude of the oscillator output signal to decrease.

Embodiments of the oscillation block 110 include a crystal 105 configured to oscillate at a particular fundamental frequency. The oscillation is tuned by tuning capacitors 112. Gain is applied to the oscillation using gain transistor 114, biased by bias resistor 116. In some embodiments, the gain transistor 114 is configured to ensure proper startup of oscillation in the crystal 105. The gain provided by the gain transistor 114 may be designed to be dependent on the magnitude of the bias current generated by current source 150.

In one embodiment, the current source 150 includes a current source transistor, the gate of which is tied to the feedback output signal from the AGC block 130. When an effective voltage level of the oscillator output signal gets close to the internal reference voltage of the AGC block 130, the AGC block 130 attenuates the bias current applied to the oscillation block 110 (e.g., applied to the gain transistor 114) by controlling the bias voltage applied to the current source transistor (e.g., by controlling the current source transistor's gate voltage). Thus, the bias current applied to the oscillation block 110 decreases and the gain provided by the gain transistor 114 is reduced. With reduced gain, the growth of the amplitude of oscillation may be controlled, helping the amplitude of the oscillator output signal reach a steady-state value.

By regulating the gain of the oscillator output signal during the startup phase, excessive gain may be avoided. Further, as excessive gain may not be available to push the crystal into higher harmonic modes of oscillation, these modes of oscillation may be avoided. Additionally, excessive amplitudes can drive a crystal oscillator over a maximum allowed drive level. Long term operation at levels exceeding the maximum allowed drive level can cause fatal damage to the crystal oscillator. Thus, controlling the gain may be desirable or even critical to proper operation of the oscillation block 110. However, it will be appreciated that optimally regulating the gain may become more difficult as the range of desired frequencies of oscillation increases. For example, it may be desirable to configure the oscillator circuit 100 for use with crystals cut for both low-frequency and high-frequency fundamental oscillations.

In a typical embodiment of the oscillator circuit 100, the current source 150 provides fixed gain. Feedback from the AGC block 130 regulated the current output from the fixed gain current source 150, but only within a limited range. When a range of oscillator frequencies is desired, the fixed gain of the current source 150 may be sub-optimal for some cases. For example, setting the gain too low may prevent startup of higher-frequency crystal oscillators, while setting the gain too high may cause lower-frequency oscillators to oscillate in undesirable harmonic modes. Still, it may be desirable to allow the AGC block 130 to operate within a narrow range as a function of the applied current, for example, to allow for the use of simpler and more robust AGC block 130 architectures. As such, embodiments of the invention address these issues to expand the range of oscillator frequencies supported by the oscillator circuit 100, while still allowing the AGC block 130 to operate within a narrow operating range as a function of an applied current.

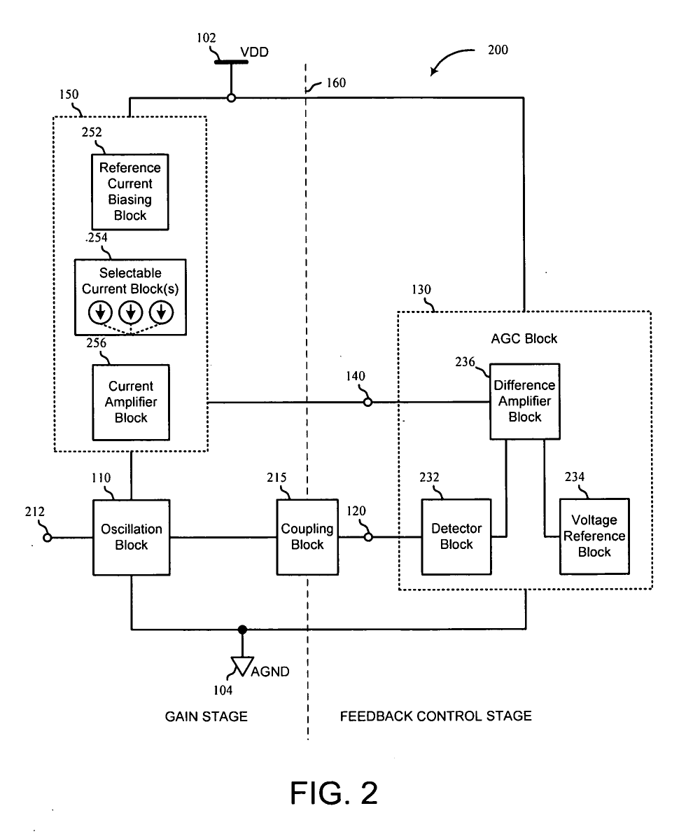

FIG. 2 shows a functional block diagram illustrating a crystal oscillator circuit 200 that supports a wide range of frequencies, according to various embodiments of the invention. As in FIG. 1, the oscillator circuit 200 includes an oscillation block 110 for generating an oscillation output signal. The oscillation block 110 is driven by a current source 150 (both shown on the left side of divider 160 as a gain stage), which is regulated in feedback by an AGC block 130 (shown on the right side of divider 160 as a feedback control stage). The current source 150 generates a desired current output at least partially from its connection to a source voltage 102.

Embodiments of the current source 150 include a reference current biasing block 252, one or more selectable current blocks 254, and a foundation current block 256. Each of the selectable current blocks 254 is configured to generate a current. In some embodiments, the selectable current blocks 254 are substantially identical, and the oscillator circuit 200 is configured to drive varying numbers of the selectable current blocks 254. In other embodiments, each of the selectable current blocks 254 is optimized for certain characteristics.

In one embodiment, the current source 150 includes three selectable current blocks 254, each driven by the reference current biasing block 252 connected to the source voltage 102. Using the selectable current blocks 254, the oscillator circuit 200 is configured to optimally regulate oscillation output signals as node 212 with crystals ranging from 4 to 48 megahertz (MHz) in four ranges: 4-8, 8-16, 16-32, and 32-48 MHz. For example, the foundation current block 256 may provide sufficient current by itself (from its connection to the source voltage 102) to drive and control crystals in the first range (4-8 MHz). One of the three selectable current blocks 254 may be switched on to provide sufficient current (from its connection to the source voltage 102 via the reference current biasing block 252) to drive and control crystals in the second range (8-16 MHz). All three selectable current blocks 254 may be switched on to provide sufficient current to drive and control crystals in the fourth range (32-48 MHz).

The selectable current blocks 254 may be selected in a number of different ways, according to various embodiments. In one embodiment, accessible switches may be provided (e.g., dip switches, buttons, etc.) for manual control of the selectable current blocks 254. In another embodiment, the selectable current blocks 254 are programmed using a programming signal. For example, a four-bit signal may be used to control four selectable current blocks 254. In still another embodiment, the oscillator circuit 200 detects an appropriate switch configuration and selects the selectable current blocks 254 accordingly. For example, the oscillator circuit 200 can read information from the crystal (e.g., an identifier that indicates the fundamental frequency of the crystal), or detect information from the operation of the crystal (e.g., the selectable current blocks 254 may start in a first configuration and adjust as characteristics of the crystal are detected).

It will be appreciated that components of the current source 150 work together to provide a relatively large range of possible current outputs from the current source 150. This large range of current outputs may provide appropriate gain levels in the oscillation block 110 to support a large range of oscillation frequencies. For example, a single oscillator circuit 200 may be designed in this way to support multiple customers having multiple desired oscillator outputs. Further, embodiments of the current source 150 are designed to provide relatively high noise immunity, relatively reliable operation at low source voltage 102 levels, etc. For example, in some embodiments, the foundation current block 256 is configured as a cascode topology.

Embodiments of the oscillator circuit 200 include additional components and/or features for improved performance. In some embodiments, a coupling block 215 is provided between the oscillation block 110 and the AGC block 130. The coupling block 215 is configured to extract a voltage level corresponding substantially to the common mode voltage level of the oscillator output signal. In one embodiment, the coupling block 215 includes a capacitor, configured to substantially smooth the oscillator output signal. The voltage level may be seen at the signal input node 120 of the AGC block 130.

In other embodiments, the AGC block 130 includes a detector block 232, a voltage reference block 234 and a difference amplifier block 236. The voltage reference block 234 is configured to generate a reference level internal to the AGC block 130. The detector block 232 is configured to generate an envelope level that corresponds substantially to the amplitude of the oscillator output signal. In some embodiments, the detector block 232 receives a voltage level from the coupling block 215 and converts the voltage level to a desired bias voltage level. The bias voltage level is then converted to the envelope level. The difference amplifier block 236 is configured to compare the envelope level from the detector block 232 against the reference level from the voltage reference block 234 to generate a feedback signal at the output signal node 140 of the AGC block 130.

In some embodiments, the AGC block 130 is designed to be highly symmetrical in topology. For example, embodiments of the voltage reference block 234 and the detector block 232 may be designed with topologies that are substantially mirror images of one another. This may provide increased noise immunity and/or other features.

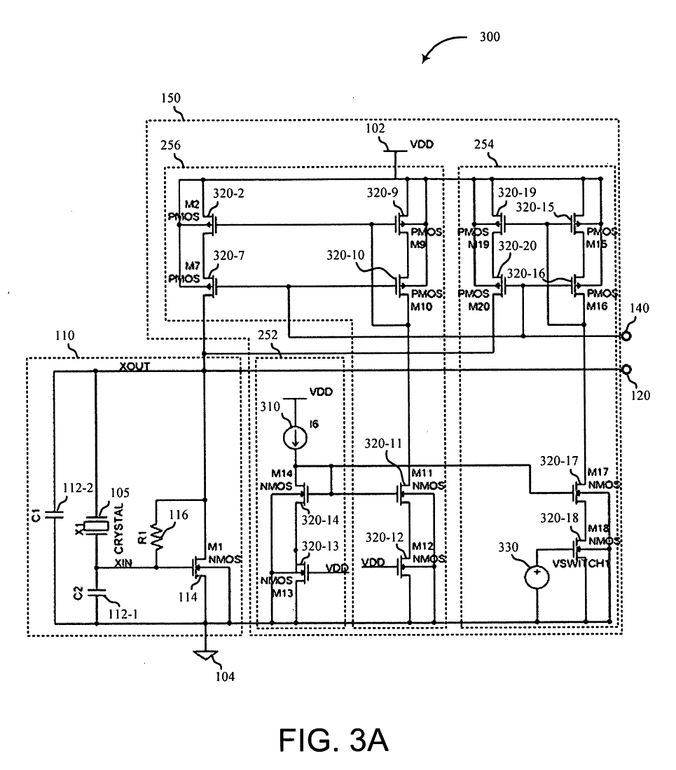

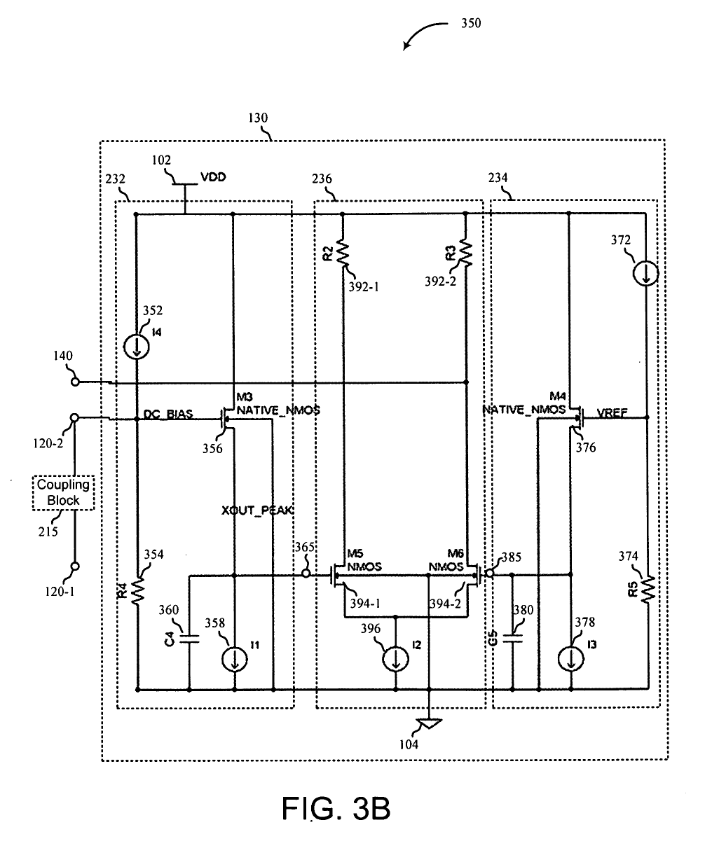

Functionality of the various components of the oscillator circuit 200 can be implemented in a number of different ways. FIGS. 3A and 3B show schematic diagrams of two portions of an oscillator circuit, like the one shown in FIG. 2, according to various embodiments of the invention. FIG. 3A shows a schematic diagram for providing illustrative gain stage functionality, like the functionality provided by components on the left side of the divider 160 in FIGS. 1 and 2 (e.g., functionality of the oscillation block 110 and the current source 150), according to various embodiments of the invention. FIG. 3B shows a schematic diagram for providing illustrative feedback control stage functionality provided by components on the right side of the divider 160 in FIGS. 1 and 2 (e.g., functionality of the AGC block 130), according to various embodiments of the invention.

Turning first to FIG. 3A, an embodiment of a gain stage circuit 300 is shown. The gain stage circuit 300 includes an oscillation block 110 and a current source 150. The current source 150 generates a desired current output at least partially from its connection to a source voltage 102. The oscillation block 110 include a crystal 105 configured to oscillate at a particular fundamental frequency. The oscillation is tuned by tuning capacitors 112. Gain is applied to the oscillation using gain transistor 114, biased by bias resistor 116. An oscillation output signal is seen on input signal node 120.

Embodiments of the current source 150 include a reference current biasing block 252, one or more selectable current blocks 254 (only one is shown), and a foundation current block 256. The reference current biasing block 252 includes a reference current source 310 connected in series with two transistors 320-14 and 320-13 between the source voltage 102 and ground 104. Transistors 320-14 and 320-13 provide a bias voltage that biases transistor 320-11 in the foundation current block 256 and transistor 320-17 in the selectable current block 254. In embodiments with additional selectable current blocks 254, the bias voltage would similarly bias respective transistors in those selectable current blocks 254.

The bias voltage may effectively mirror the current from the reference current biasing block 252 into NMOS transistors 320-11 and 320-12 in the foundation current block 256. The current is then effectively mirrored from NMOS transistors 320-11 and 320-12 into PMOS transistors 320-2 and 320-7 via PMOS transistors 320-9 and 320-10. PMOS transistors 320-2 and 320-7 are configured to provide a foundation current to the oscillation block 110.

The selectable current blocks 254 each include a selector 330 configured to enable and/or disable the selectable current block 254. As discussed above, the selector 330 may be selected in a number of different ways according to different embodiments. When the selector 330 is configured to enable the selectable current block 254, the NMOS transistor 320-18 is turned on, by effectively mirroring the current from the reference current biasing block 252 into NMOS transistors 320-17 and 320-18 in the selectable current block 254. As with the foundation current block 256 operation, the current is then effectively mirrored from NMOS transistors 320-17 and 320-18 into PMOS transistors 320-19 and 320-20 via PMOS transistors 320-15 and 320-16. PMOS transistors 320-19 and 320-20 are configured to provide additional current to the oscillation block 110. It will be appreciated that additional selectable current blocks 254 may be provided in the gain stage circuit 300 to provide additional current to the oscillation block in substantially the same way.

It is worth noting that the pair of PMOS transistors 320-2 and 320-7 in the foundation current block 256 and the pair of PMOS transistors 320-19 and 320-20 in the selectable current block 254 are each configured as a cascode topology. The upper transistor of each pair (e.g., transistors 320-2 and 320-19) are connected to the source voltage 102. Each of the lower transistors (e.g., transistors 320-7 and 320-20) is connected in a source follower configuration, providing current to the oscillation block 110. The cascode topology may provide relatively high immunity to noise on the source voltage 102, for example, depending on the operating regions of the transistors 320-2 and 320-7.

It is further worth noting that the gate of each lower transistor in each cascode pair (e.g., transistors 320-7 and 320-20) is connected to output signal node 140. As shown in FIGS. 1 and 2, the output signal node 140 is in communication with the output of an AGC block (e.g., like the AGC block 130 of FIG. 1 or 2). The AGC block receives the oscillator output signal via the input signal node 120 and adjusts the voltage level on the output signal node 140. By adjusting the voltage level on the output signal node 140, the amount of current sourced by transistors 320-2 and 320-19 may be adjusted. In this way, the foundation current provided by the foundation current block 256 and additional currents provided by one or more selectable current blocks 254 can be adjusted in parallel to regulate the amplitude of the oscillator output signal. By selectively enabling or disabling selectable current blocks 254, appropriate gain ranges may be provided, optimized for different oscillation frequencies.

While different types of feedback control stages (e.g., AGC blocks) may be used, some embodiments include the feedback control stage circuit 350 shown in FIG. 3B. The feedback control stage circuit 350 includes a detector block 232, a voltage reference block 234, and a difference amplifier block 236. The detector block 232 is in communication with the output of a gain stage, like the gain stage circuit 300 of FIG. 3A, via input signal node 120. In some embodiments, the output of the gain stage is received at node 120-1 and converted into a voltage level at node 120-2 by a coupling block 215.

An input signal corresponding to the oscillator output signal amplitude is received at a node connecting a first detector current source 352 to a detector resistor 354. The detector current source 352 and the detector resistor 354 are connected in series between a source voltage 102 and ground 104 and act on the input signal to generate a desired bias voltage level. The bias voltage level may be mathematically related to the input signal (e.g., and thereby to the amplitude of the oscillator output signal), but shifted to a level desired for operation of the detector block 232.

The bias voltage level is applied to a detector transistor 356, which generates an envelope level with the help of a second detector current source 358 connected, between an envelope level output node 365 and ground 104, in parallel with a detector capacitor 360. The envelope level at the envelope level output node 365 corresponds substantially to an amplitude of an oscillator output signal generated by a gain stage circuit (e.g., the gain stage circuit 300 of FIG. 3A) in communication with the feedback control stage circuit 350.

As discussed above, some embodiments of the voltage reference block 234 are designed substantially as the mirror image of the detector block 232. This symmetric topology may provide certain features, including, for example, increasing noise immunity, increasing design modularity, etc. As in the detector block 232, a first reference current source 372 and a reference resistor 374 generate a reference voltage level. The reference voltage level is applied to a reference transistor 376, which generates a reference level with the help of a second reference current source 378 connected, between a reference level output node 385 and ground 104, in parallel with a reference capacitor 380.

Embodiments of the difference amplifier block 236 are designed to maintain the symmetric topology of the detector block 232 and the voltage reference block 234. The envelope level at the envelope level output node 365 is received at the gate of a first comparing transistor 394-1 and the reference level at the reference level output node 385 is received at the gate of a second comparing transistor 394-2. Each comparing transistor 394 is connected in series through a respective comparing resistor 392 to the source voltage 102. Each comparing transistor 394 is also connected to comparing current source 396, which is connected to ground 104.

At initial startup, the envelope level at the envelope level output node 365 is substantially at zero (e.g., the amplitude of the oscillator output signal starts at zero), causing substantially no current to flow through the first comparing transistor 394-1 and its respective first comparing resistor 392-1. Because the comparing current source 396 draws a constant current, substantially all its current flows through the second comparing transistor 394-2 and its respective second comparing resistor 392-2. As such, the voltage drop across the second comparing resistor 392-2 will be at a highest level, causing the output signal node 140, which is connected to the bottom of the second comparing resistor 392-2, to be at a lowest level.

As the amplitude of the oscillator output signal increases, the envelope level at the envelope level output node 365 also increases, thereby increasing current flow through the first comparing transistor 394-1 and its respective first comparing resistor 392-1. This, in turn, causes current flow to decrease through the second comparing transistor 394-2 and its respective second comparing resistor 392-2. As such, the voltage drop across the second comparing resistor 392-2 decreases, causing the output signal node 140, which is connected to the bottom of the second comparing resistor 392-2, to increase.

The increasing voltage level on the output signal node 140 is fed back to the gain stage, causing the gain applied to the oscillator output signal to be reduced. For example, in the gain stage circuit 300 of FIG. 3A, the output signal node 140 controls the gates of the lower transistors in each cascode pair (e.g., transistors 320-7 and 320-20). Because the lower transistors are PMOS devices, increasing the voltage at their gates may cause an increase in their respective source voltages (e.g., because they are configured in a source follower topology). The increase in source voltage may cause the current flow through transistors 320-2 and 320-19 to be reduced, thereby causing less gain to be applied to the oscillator output signal. In this way, as the amplitude of the oscillator output signal increases, the gain applied to the oscillator output signal decreases by feedback from the feedback control stage.

It will now be appreciated that the gain stage circuit of FIG. 3A and the feedback control stage circuit of FIG. 3B can operate to control the amplitude of oscillation in reaching a steady-state. By controlling the gain of the oscillator during the startup phase, excessive gain may be avoided. Further, unwanted higher harmonic modes may be avoided, since excessive gain is not available to push the crystal into those harmonic modes. As such, it may be possible to maintain reliable operation for crystals over a wide frequency range, for example, a 12:1 ratio.

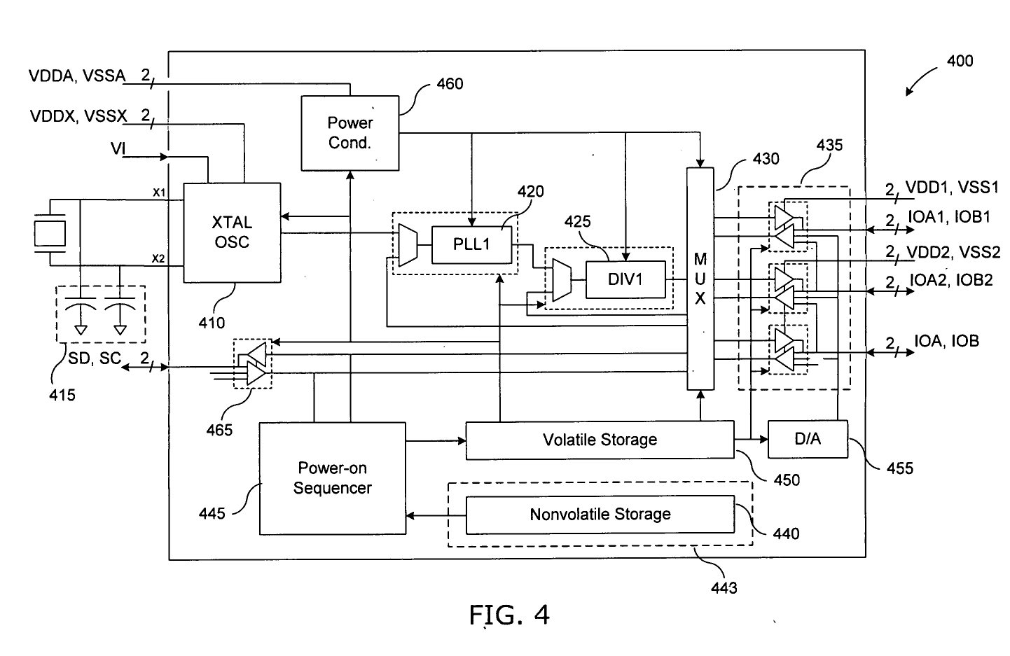

FIG. 4 illustrates another simplified block diagram of a circuit arrangement 400, for use with various embodiments of the invention. An external crystal is connected to a crystal oscillator (“XO”) 410 in an exemplary embodiment. A pair of capacitors 415 connect crystal oscillator inputs X1, X2 to ground. XO power (“VDDX”), XO ground (“VSSX”), and XO input voltage (“VI”) are external inputs to the XO 410. In some embodiments, the XO 410 is implemented as a voltage controlled crystal oscillator, controlled, for example, by VI. In some embodiments, the XO 410 is implemented according to the oscillator circuitry of FIGS. 1-3. The oscillator circuits may provide stable and selectable frequency of operation over a wide range of crystals and corresponding operating frequencies.

An output of the XO 410 is connected with an input multiplexer (mux) of a phase lock loop (“PLL1”) 420, providing a reference signal for the PLL 420. In some embodiments, additional PLLs 420 may be used to allow for additional I/Os and further programmability. An output of the phase lock loop 420 is connected with an input multiplexer (mux) of a PLL divider (DIV1) 425. An output of the PLL divider 425 is fed to a MUX 430. Outputs of the MUX 430 are connected with programmable input/output buffers 435.

The clock generator circuit 400, including a nonvolatile storage array 440, may be fabricated, for example, in a single monolithic semiconductor substrate or alternately, the nonvolatile storage array 440 may reside on a second semiconductor substrate 443. An output of the nonvolatile storage array 440 may be in communication with a power-on sequencer 445. The power-on sequencer 445 may communicate with a volatile storage array 450.

The volatile storage array 450 is in communication with a digital-to-analog (D/A) block 455, a power conditioner block 460, a serial input/output (“I/O”) block 465, the programmable I/O buffers 435, the mux 430, the PLL 420, the PLL divider 425, and the XO 410. The serial I/O block 465 communicates with serial data and serial clock inputs SD, SC, the power-on sequencer 445, and the MUX 430. The power conditioner block 460 is connected with PLL power inputs VDDA, VSSA.

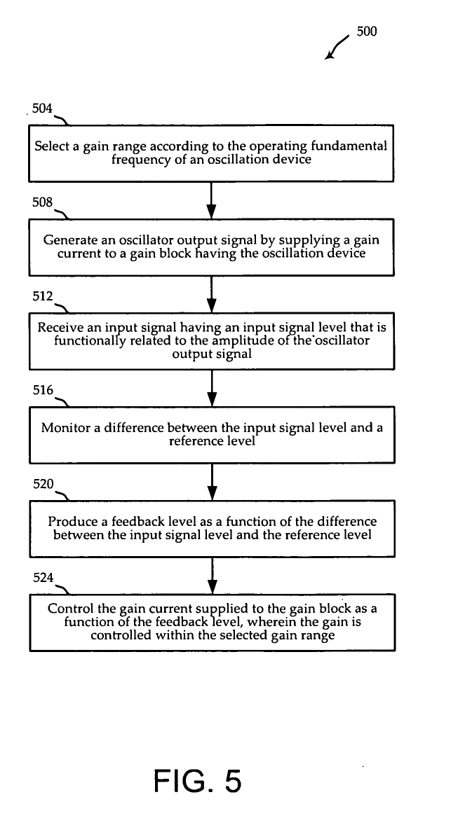

It will be appreciated that the circuits described above provide only exemplary systems for providing functionality according to embodiments of the invention. For example, those and other embodiments may perform the method of FIG. 5. FIG. 5 shows a flow diagram of a method 500 for regulating an amplitude of an oscillator output signal, according to various embodiments of the invention.

In some embodiments, the method begins at block 504 by selecting a gain range according to the operating fundamental frequency of an oscillation device. Various gain ranges may be desirable for optimally driving oscillators at various frequencies. For example, relatively high gains may be needed to initiate oscillation of high-frequency oscillators, but high gains may cause low-frequency oscillators to oscillate at undesired higher-order harmonics.

The method 500 may then generate an oscillator output signal at block 508 by supplying a gain current to a gain block having the oscillation device. At block 512, an input signal is received, having an input signal level that is functionally related to the amplitude of the oscillator output signal. For example, at startup, the amplitude of the oscillator output signal may be substantially zero, and the input signal level may correspondingly be substantially at zero.

At block 516, a difference between the input signal level and a reference level may be monitored. This difference may then be used at block 520 to produce a feedback level. In some embodiments, the input signal level and the feedback level are directly related, such that the feedback level rises when the input signal level rises. In other embodiments, the input signal level and the feedback level are inversely related, such that the feedback level falls when the input signal level rises.

The gain current supplied to the gain block is controlled at block 524 as a function of the feedback level. Typically, the gain may be controlled within the selected gain range. In some embodiments, the feedback level provides negative feedback, such that the gain and the input signal level are inversely related. In this way, as the input signal level rises (e.g., as the amplitude of the oscillator output signal rises), the gain is reduced, causing the amplitude of the oscillator output signal to be controlled.

It should be noted that the methods, systems, and devices discussed above are intended merely to be examples. It must be stressed that various embodiments may omit, substitute, or add various procedures or components as appropriate. For instance, it should be appreciated that, in alternative embodiments, the methods may be performed in an order different from that described, and that various steps may be added, omitted, or combined. Also, features described with respect to certain embodiments may be combined in various other embodiments. Different aspects and elements of the embodiments may be combined in a similar manner. Also, it should be emphasized that technology evolves and, thus, many of the elements are examples and should not be interpreted to limit the scope of the invention.

It should also be appreciated that the following systems and methods may individually or collectively be components of a larger system, wherein other procedures may take precedence over or otherwise modify their application. Also, a number of steps may be required before, after, or concurrently with the following embodiments. Specific details are given in the description to provide a thorough understanding of the embodiments. However, it will be understood by one of ordinary skill in the art that the embodiments may be practiced without these specific details. For example, well-known circuits, processes, algorithms, structures, and techniques have been shown without unnecessary detail in order to avoid obscuring the embodiments.

Also, it is noted that the embodiments may be described as a process which is depicted as a flow diagram or block diagram. Although each may describe the operations as a sequential process, many of the operations can be performed in parallel or concurrently. In addition, the order of the operations may be rearranged. A process may have additional steps not included in the figure.

Accordingly, the above description should not be taken as limiting the scope of the invention, which is defined by the appended claims.

What is claimed is:

1. An oscillator circuit comprising:
a gain module, configured to output an oscillator output signal as a function of applying a gain current to an oscillation device;
a comparison module, in operative communication with the gain module and configured to:
receive an input signal having an input signal level that is functionally related to an amplitude of the oscillator output signal;
monitor a difference between the input signal level and a reference level; and
produce a feedback level as a function of the difference between the input signal level and the reference level; and
a current source module, comprising:
a first current block, in operative communication with the comparison block and the gain module, and configured to generate at least a first portion of the gain current as a function of the feedback level and to provide at least the first portion of the gain current to the gain module; and
a second current block, in operative communication with the comparison block and the gain module, and configured to be enabled to generate at least a second portion of the gain current as a function of the feedback level and to provide at least the second portion of the gain current to the gain module.

2. The oscillator circuit of claim 1, wherein the first current block comprises:
a cascode topology having a first transistor and a second transistor, the first transistor being coupled between a reference voltage and the second transistor, and the second transistor being coupled between the first transistor and the gain module, such that the second transistor is substantially isolated from noise present on the reference voltage.

3. The oscillator circuit of claim 1, wherein the current source module comprises a plurality of current blocks, each of the plurality of current blocks having a substantially identical topology.

4. The oscillator circuit of claim 1, further comprising:
a select device configured to enable the second current block as a function of a selection input.

5. The oscillator circuit of claim 4,
wherein the select device is a voltage-controlled switch and the selection input is a voltage level configured to enable the second current block by activating the voltage-controlled switch.

6. The oscillator circuit of claim 1, wherein the current source module comprises:
a number of current blocks related to a predetermined number of current source configurations, at least some of the number of current blocks being configurable current blocks configured to be enabled to generate at least a portion of the gain current as a function of the feedback level and to provide at least the portion of the gain current to the gain module, each current source configuration defining which of the configurable current blocks is enabled.

7. The oscillator circuit of claim 6, wherein each of the configurable current blocks comprises:
a switch in communication with a configuration enable signal, the configuration enable signal being configured to enable a set of the configurable current blocks according to a selected one of the number of current source configurations.

8. The oscillator circuit of claim 6, wherein:
the oscillation device is one of a set of oscillation device types, each oscillation device type being associated with one of a set of operating gain ranges; and
each current source configuration corresponds to one of the set of operating gain ranges.

9. The oscillator circuit of claim 8, wherein each current source configuration corresponds to one of the set of operating gain ranges by enabling the number of current blocks as defined by the current source configuration, such that the current source is configured to control the gain module for operation of the oscillation device within its associated one of the set of gain ranges.

10. The oscillator circuit of claim 1, wherein the comparison module comprises:
a detector block, configured to detect the amplitude of the oscillator output signal and generate the input signal.

11. The oscillator circuit of claim 1, wherein the comparison module comprises
a reference block, configured to generate the reference level.

12. The oscillator circuit of claim 1, wherein the comparison module comprises:
a detector block, configured to detect the amplitude of the oscillator output signal and generate the input signal;
a reference block, configured to generate the reference level; and
a difference amplifier block, configured to monitor a difference between the input signal level and the reference level and produce the feedback level as a function of the difference between the input signal level and the reference level.

13. The oscillator circuit of claim 12, wherein:
the detector block is configured with a first topology;
the reference block is configured with a second topology; and
the second topology is functionally a substantially mirror image of the first topology.

14. The oscillator circuit of claim 12, wherein the detector block comprises a coupling device configured to generate a bias level as a function of the amplitude of the oscillator output signal, the input signal being generated as a function of the bias level.

15. The oscillator circuit of claim 1, wherein the comparison module comprises:
a comparison current source, configured to source a substantially constant magnitude of current from a top node to ground;
a first branch coupled between a voltage reference and the top node, comprising a first load device and a first current regulation device, the first current regulation device being configured to regulate current through the first branch as a function of the input signal level; and
a second branch coupled between the voltage reference and the top node, comprising a second load device coupled with a second current regulation device at a feedback node, the second current regulation device being configured to regulate current through the second branch as a function of the reference signal level,
wherein the feedback level is produced at the feedback node.

16. The oscillator circuit of claim 1, wherein the oscillating device is a crystal configured to oscillate at a fundamental frequency.

17. An oscillator circuit comprising:
a gain stage coupled to a supply voltage reference node and configured to provide a magnitude of gain corresponding to a feedback signal, the gain stage comprising a plurality of gain sources, each of the gain sources being in communication with the feedback signal, and at least one of the gain sources being configured to be disabled; and
a gain control stage, coupled to the gain stage and configured to measure a magnitude of difference between an input signal level and a reference signal level and produce the feedback signal proportional to the difference measured.

18. A method for regulating an amplitude of an oscillation output signal, the method comprising:
receiving an input signal having an input signal level that is functionally related to the amplitude of the oscillator output signal, the oscillator output signal being generated as a function of applying a gain current to an oscillation device, the oscillation device being configured to oscillate substantially at a fundamental frequency;
monitoring a difference between the input signal level and a reference level;
producing a feedback level as a function of the difference between the input signal level and the reference level; and
controlling the gain current as a function of the feedback level, wherein the gain is controlled within a gain range selected according to the fundamental frequency of the oscillation device.

19. The method of claim 18, further comprising:
generating a source current from a voltage source,
wherein controlling the gain current as a function of the feedback level comprises regulating the current output of a current regulation device substantially isolated from noise present at the voltage source, the current output being generated as a function of the source current and the feedback level.

20. The method of claim 18, further comprising:
selecting a gain range according to the fundamental frequency of the oscillation device by configuring a programmable current source to generate the gain current as a function of the gain range.

21. The method of claim 18, wherein producing a feedback level as a function of the difference between the input signal level and the reference level comprises:
tying a first current in a first branch and a second current in a second branch to a third current in a third branch such that the sum of the first current and the second current is substantially equal to the third current;
regulating the first current in the first branch as a function of the input signal level;
regulating the second current in the second branch as a function of the reference level, the second branch comprising a feedback node having a voltage level corresponding to the feedback level, such that the feedback level is functionally related to the second current.

22. The method of claim 21, wherein the feedback node is configured such that the feedback level increases when the input signal level increases.
